(19) United States
(12) Patent Application Publication
(10) Pub. No.: US 2006/0043452 A1
(43) Pub. Date: Mar. 2, 2006

(54) Ferroelectric memory and its manufacturing method

(76) Inventors: Mamoru Ueda, Suwa (JP); Kazuhiro Masuda, Fujimi (JP); Shinichi Fukada, Hamura (JP)

Correspondence Address: HARNESS, DICKEY & PIERCE, P.L.C., P.O. BOX 828, BLOOMFIELD HILLS, MI, 48303, US

(21) Appl. No.: 11/210,011

(22) Filed: Aug. 23, 2005

(30) Foreign Application Priority Data
Aug. 25, 2004 (JP) 2004-245362

(51) Int. Cl. H01L 29/94

(52) U.S. Cl. 257/310

(57) ABSTRACT

A ferroelectric memory includes a base member, a dielectric layer formed above the base member, a contact hole that penetrates the dielectric layer, a plug formed inside the contact hole, a barrier layer formed above the plug, and including a first portion with a portion formed in the contact hole and a second portion formed integrally with the first portion and above the dielectric layer, and a ferroelectric capacitor formed from a lower electrode, a ferroelectric layer and an upper electrode successively laminated in a region including above the plug.

### RELATED APPLICATIONS

This application claims priority to Japanese Patent Application No. 2004-245362 filed Aug. 25, 2004 which is hereby expressly incorporated by reference herein in its entirety.

### BACKGROUND

1. Technical Field

The present invention relates to ferroelectric memories and methods for manufacturing the same.

2. Related Art

For ferroelectric memories, the structure in which a ferroelectric capacitor is stacked on a selection transistor is known. A dielectric layer is provided between the ferroelectric capacitor and the selection transistor, and an electrical connection between them is made by a plug embedded in a contact hole in the dielectric layer. The plug is formed by forming a film of conductive layer that is a plug material inside the contact hole and on the dielectric layer, and the entire conductive layer is polished by using a chemical mechanical polishing (CMP) method or the like. However, in this case, a recess (concave section), which is caused by a difference in the polishing rate between the conductive layer and the surrounding dielectric layer, is generated in the conductive layer at the contact hole. If the recess is left remained, the ferroelectric capacitor cannot be formed on a flat surface, the stability in the manufacturing process is damaged, and the reliability may possibly be lowered. It is noted that, in the process of manufacturing the ferroelectric capacitor, a process of oxidizing the ferroelectric layer is necessary, and therefore prevention of oxidation of the plug is required.

It is an object of the present invention to provide ferroelectric memories that can simplify the manufacturing process and improve the reliability, and methods for manufacturing the same.

### SUMMARY

A ferroelectric memory in accordance with the present invention includes:

a base member;

a dielectric layer formed above the base member;

a contact hole that penetrates the dielectric layer;

a plug formed inside the contact hole;

a barrier layer formed above the plug, and including a first portion with a portion formed inside the contact hole and a second portion formed integrally with the first portion and above the dielectric layer; and

a ferroelectric capacitor formed from a lower electrode, a ferroelectric layer and an upper electrode successively laminated in a region including above the plug.

According to the present invention, the barrier layer is formed in a wide area that extends from the contact hole over the dielectric layer, such that oxidation of the plug can be prevented, and the adhesion to the lower electrode of the ferroelectric capacitor can be improved. Accordingly, a highly reliable ferroelectric memory can be provided with a fewer number of components.

It is noted that, in the present invention, a case in which a layer B provided above a specific layer A includes a case where a layer B is provided directly on a layer A, and a case where a layer B is provided above a layer A through another layer. This similarly applies to the following inventions.

In the ferroelectric memory, an upper surface of the barrier layer may be flat.

In the ferroelectric memory, the barrier layer may be formed in a region including the lower electrode.

In the ferroelectric memory, the barrier layer may include one of a titanium aluminum nitride layer and a titanium nitride layer.

The ferroelectric memory may further include an adhesion layer that is formed between the lower electrode and the barrier layer, and is formed in a region including the lower electrode.

The ferroelectric memory may further include another barrier layer formed along an inner surface of the contact hole, wherein the plug may be formed inside the another barrier layer.

A method for manufacturing a ferroelectric memory in accordance with the present invention includes:

(a) forming a contact hole that penetrates a dielectric layer formed above a base member;

(b) forming a first conductive layer inside the contact hole and above the dielectric layer;

(c) forming a plug inside the contact hole, having an upper surface at a position lower than an upper surface of the dielectric layer, by polishing the first conductive layer until the dielectric layer is exposed;

(d) forming a second conductive layer inside the contact hole and above the dielectric layer;

(e) forming a barrier layer formed above the plug, and including a first portion with a portion formed inside the contact hole and a second portion formed integrally with the first portion and above the dielectric layer by polishing the second conductive layer to a predetermined thickness to be remained above the dielectric layer; and

(f) forming a ferroelectric capacitor by successively laminating a lower electrode, a ferroelectric layer and an upper electrode in a region including above the plug.

According to the present invention, the barrier layer is formed in a wide area that extends from the contact hole over the dielectric layer, such that oxidation of the plug can be prevented, and the adhesion to the lower electrode of the ferroelectric capacitor can be improved. Also, because the barrier layer can be formed by polishing the second conductive layer that has been formed, for example, the film forming step does not need to be conducted multiple times, and therefore the manufacturing process can be simplified. Furthermore, in the step of polishing the barrier layer, only the second conductive layer is polished, and therefore a recess that may be caused by a difference in the polishing rate among different kinds of materials can be prevented from being generated.

The method for manufacturing a ferroelectric memory may further include forming another barrier layer along an inner surface of the contact hole, before the step (b), wherein the plug may be formed inside the another barrier layer in the step (c).

In the method for manufacturing a ferroelectric memory, at least one of the step (c) and the step (e) may include a step conducted by a chemical mechanical polishing method.

In the method for manufacturing a ferroelectric memory, in the step (c), an upper portion of the first conductive layer inside the contact hole may be further removed by etching.

By this, the upper portion of the first conductive layer is further removed, such that the barrier layer can be formed much thicker.

In the method for manufacturing a ferroelectric memory, in the step (f), the lower electrode, the ferroelectric layer and the upper electrode may be successively laminated to form a laminated body, and the laminated body and the barrier layer may be patterned in a common process.

By this, because the laminated body that becomes to be a ferroelectric capacitor and the barrier layer are patterned in the same process, the manufacturing process can be simplified.

The method for manufacturing a ferroelectric memory may further include forming an adhesion layer in a region including above the barrier layer, after the step (e), wherein the ferroelectric capacitor may be formed above the adhesion layer in the step (f).

In the method for manufacturing a ferroelectric memory, in the step (f), the lower electrode, the ferroelectric layer and the upper electrode may be successively laminated to form a laminated body, and the laminated body, the barrier layer and the adhesion layer may be patterned in a common process.

By this, because the laminated body that becomes to be a ferroelectric capacitor, the barrier layer and the adhesion layer are patterned in the same process, the manufacturing process can be simplified.

### BRIEF DESCRIPTION OF THE DRAWINGS

FIG. 1 is a view showing a ferroelectric memory in accordance with a first embodiment of the present invention.

FIG. 2 is a view showing a method for manufacturing the ferroelectric memory in accordance with the first embodiment of the present invention.

FIG. 3 is a view showing the method for manufacturing the ferroelectric memory in accordance with the first embodiment of the present invention.

FIG. 4 is a view showing the method for manufacturing the ferroelectric memory in accordance with the first embodiment of the present invention.

FIG. 5 is a view showing the method for manufacturing the ferroelectric memory in accordance with the first embodiment of the present invention.

FIG. 6 is a view showing the method for manufacturing the ferroelectric memory in accordance with the first embodiment of the present invention.

FIG. 7 is a view showing the method for manufacturing the ferroelectric memory in accordance with the first embodiment of the present invention.

FIG. 8 is a view showing the method for manufacturing the ferroelectric memory in accordance with the first embodiment of the present invention.

FIG. 9 is a view showing the method for manufacturing the ferroelectric memory in accordance with the first embodiment of the present invention.

FIG. 10 is a view showing a ferroelectric memory in accordance with a second embodiment of the present invention.

FIG. 11 is a view showing a method for manufacturing the ferroelectric memory in accordance with the second embodiment of the present invention.

FIG. 12 is a view showing the method for manufacturing the ferroelectric memory in accordance with the second embodiment of the present invention.

### DETAILED DESCRIPTION

Embodiments of the present invention are described below with reference to the accompanying drawings.

### First Embodiment

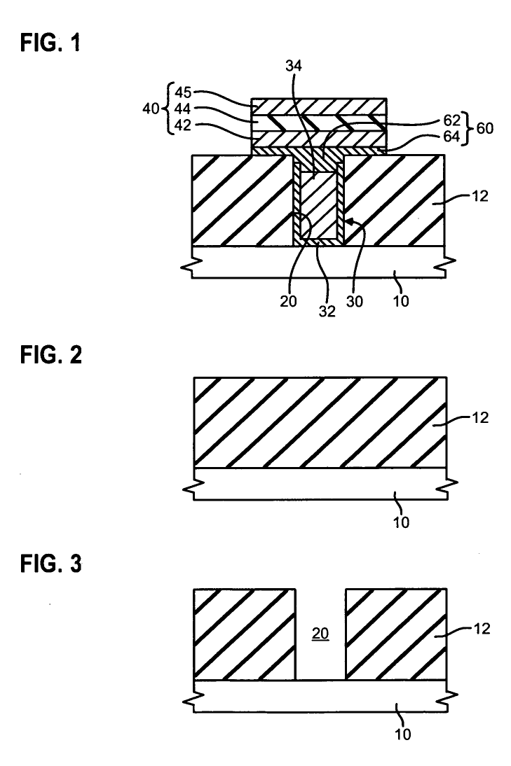

FIG. 1 is a view schematically showing a ferroelectric memory in accordance with a first embodiment of the present invention.

The ferroelectric memory in accordance with the present embodiment includes a base member 10, a dielectric layer 12, a contact hole 20, a contact section 30, and a ferroelectric capacitor 40.

The base member 10 is a semiconductor substrate (for example, a silicon substrate). A plurality of transistors (not shown) is formed in the base member 10. Each transistor includes an impurity region that becomes to be a source region or a drain region, a gate dielectric layer, and a gate electrode. An element isolation region (not shown) is formed between adjacent transistors, to provide electrical insulation between the transistors. The ferroelectric memory in accordance with the present embodiment is, for example, a 1T1C type with a stacked structure.

The dielectric layer 12 is formed on the base member 10. The dielectric layer 12 may be formed from at least one of, for example, a silicon oxide layer (SiO₂ layer), a silicon nitride layer (SiN layer), a silicon oxinitride layer (SiON layer) and an aluminum oxide layer (Al₂O₃ layer), and may be composed of a single layer or a plurality of layers.

The contact hole 20 penetrates the dielectric layer 12. The contact section 30 having an electrical conductivity is formed in the contact hole 20.

The contact section 30 is formed extending in a direction orthogonal to a surface of the base member 10, and penetrates the dielectric layer 12. One of end sections of the contact section 30 is electrically connected to a transistor (either a source region or a drain region) in the base substrate 10, and the other end section is electrically connected to the ferroelectric capacitor 40. In other words, the contact section 30 electrically connects the transistor and the ferroelectric capacitor 40.

The contact section 30 includes a plug 34 and a barrier layer 60. In the example shown in FIG. 1, the contact section 30 further includes another barrier layer 32 formed along an inner surface (bottom surface and side surface) of the contact hole 20. In this case, the plug 34 is formed on the inside surrounded by the barrier layer 32. The plug 34 is formed inside the contact hole 20, and may be formed from, for example, a tungsten (W) layer.

In the present embodiment, the barrier layer 60 includes first and second sections 62 and 64. The first section 62 of the barrier layer 60 is a portion on the plug 34, and a portion thereof is formed inside the contact hole 20. On the other hand, the second section 64 of the barrier layer 60 is formed integrally with the first portion 62 on the dielectric layer 12. In other words, the barrier layer 60 is formed in a shape having a cross section of a letter T on the plug 34. An upper surface (an upper surface of the T shape) of the barrier layer 60 may be flat.

The barrier layer 60 is formed in a region including the lower electrode 42 of the ferroelectric capacitor 40 to be described below. In other words, in a plan view viewed in a direction orthogonal to the surface of the base member 10, a plane area of the barrier layer 60 includes at least a plane area of the lower electrode 42. For example, the plane area of the barrier layer 60 may generally match with the plane area of the lower electrode 42. It is noted that the barrier layer 60 may have a greater adhesion to the lower electrode 42 than to the plug 34.

The barrier layer 60 may be formed from at least one of, for example, a titanium aluminum nitride layer (TiAlN layer) and a titanium nitride layer (TiN layer). The barrier layer 32 formed along the inner surface of the contact hole 20 may be formed from the same material as that of the barrier layer 60 provided on the plug 34. The barrier layers 32 and 60 make diffusion prevention and oxidation prevention for the plug 34 possible, and the resistance of the contact section 30 can be lowered.

The ferroelectric capacitor 40 is formed in a region including a region above the plug 34 (the contact section 30). In other words, in a plan view viewed in a direction orthogonal to the surface of the base member 10, a plane area of the ferroelectric capacitor 40 includes the plug 34 and its surrounding area (the dielectric layer 12).

The ferroelectric capacitor 40 is formed from a lower electrode 42, a ferroelectric layer 44 and an upper electrode 46 successively laminated. The lower electrode 42 is electrically connected to the plug 34 through the barrier layer 60. More specifically, the lower electrode 42 of the ferroelectric capacitor 40 is electrically connected to either the source region or the drain region of the transistor. In the ferroelectric memory of the present embodiment, the lower electrode 42 of the ferroelectric capacitor 40 is electrically connected to a bit line, and the upper electrode 46 of the ferroelectric capacitor 40 is electrically connected to a plate line, and a gate electrode of the transistor is electrically connected to a word line.

The lower electrode 42 and the upper electrode 46 may be formed from, for example, Pt, Ir, Ir oxide (IrOₓ), Ru, Ru oxide (RuOₓ), SrRu compound oxide (SrRuOₓ), or the like. Each of the lower electrode 42 and the upper electrode 46 may be formed from a single layer, or a plurality of layers.

The ferroelectric layer 44 may be formed with a PZT type ferroelectric composed of oxides including Pb, Zr and Ti as constituting elements. Alternatively, Pb (Zr, Ti, Nb) O₃ (PZTN type) in which Nb is doped at the Ti site may be used. Alternatively, the ferroelectric layer 44 may not be limited to these materials, and for example, any of SBT type, BST type, BIT type and BLT type material can be used.

In the ferroelectric memory in accordance with the present embodiment, the barrier layer 60 is formed in a wide area extending from the contact hole 20 over the dielectric layer 12, such that the plug 34 can be prevented from oxidation, and the adhesion to the lower electrode 42 of the ferroelectric capacitor 40 can be improved. Accordingly, a highly reliable ferroelectric memory can be provided with a fewer number of components.

Next, a method for manufacturing a ferroelectric memory in accordance with an embodiment is described. FIG. 2-FIG. 9 are views schematically showing a method for manufacturing a ferroelectric memory in accordance with the present embodiment.

As shown in FIG. 2, a dielectric layer 12 is formed on a base member 10. The dielectric layer 12 is formed on a surface of the base member 10 where plural transistors are formed. The dielectric layer 12 may be formed by using a known technique such as a CVD (chemical vapor deposition) method.

As shown in FIG. 3, a contact hole 20 that penetrates the dielectric layer 12 is formed. In this case, a photolithography technique may be used. More specifically, a resist layer (not shown) that opens over a portion of the dielectric layer 12 is formed. The portion that opens through the resist layer is etched, thereby forming the contact hole 20 that penetrates the dielectric layer 12. The base member 10 is exposed through the contact hole 20.

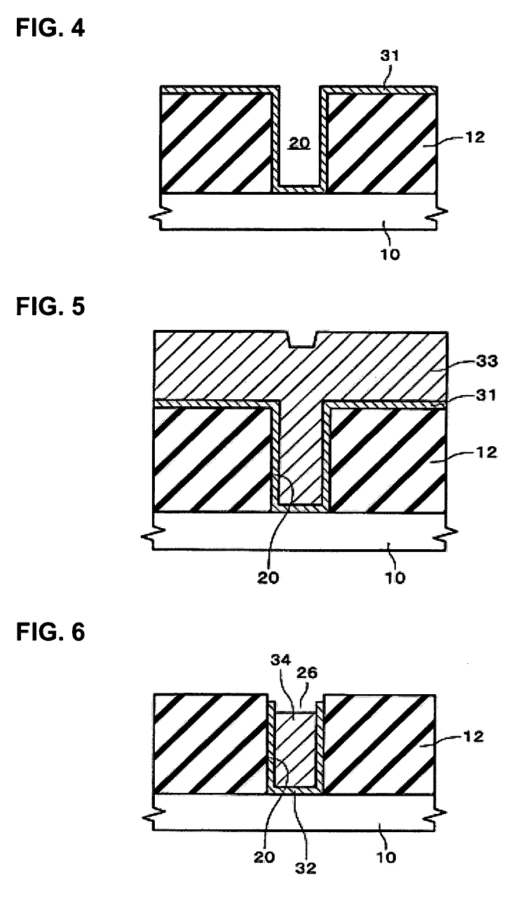

As shown in FIG. 4 through FIG. 8, a contact section 30 is formed in the contact hole 20. In the present embodiment, the contact section 30 includes a plug 34, and barrier layers 32 and 60.

First, as shown in FIG. 4, a barrier layer (another barrier layer) 31 is formed along an inner surface of the contact hole 20. The barrier layer 31 may be formed by sputtering or the like. The barrier layer 31 is formed on a side surface (an end face of the dielectric layer 12) of the contact hole 20 and a bottom surface (an upper surface of the base member 10) of the contact hole 20, and on an upper surface of the dielectric layer 12 in a manner to be continuous with the portion formed inside the contact hole 20. However, the barrier layer 31 is formed in a manner not to embed the contact hole 20.

Next, as shown in FIG. 5, a first conductive layer 33 is formed inside the contact hole 20 and on the dielectric layer 12. The first contact layer 33 is formed in a manner that the interior (more specifically, the inside surrounded by the barrier layer 31) of the contact hole 20 is embedded. When the barrier layer 31 is formed, the first conductive layer 33 is formed on the barrier layer 31. The first conductive layer 33 may be formed by sputtering or the like.

Then, as shown in FIG. 6, the first conductive layer 33 is polished. In the present embodiment, a portion of the first conductive layer 33 and a portion of the barrier layer 31 are polished and removed. In other words, the first conductive layer 33 (and the barrier layer 31) is polished until the dielectric layer 12 that serves as a stopper is exposed. In the polishing process, a process by a chemical mechanical polishing (CMP) method may be used. Because the dielectric layer 12 has a property that is more difficult to be polished than the first conductive layer 33, the first conductive layer 33 is more preferentially polished than the dielectric layer 12. As a result, a recess (a concave portion 26) defined by the first conductive layer 33 is generated inside the contact hole 20. It is noted that, when the barrier layer 31 is more readily polished than the dielectric layer 12, the barrier layer 31 is also preferentially polished than the dielectric layer 12, and an upper portion of the barrier layer 31 inside the contact hole 20 is also polished and removed, as shown in FIG. 6.

After the aforementioned polishing process is completed, an upper portion of the first conductive layer 33 (plug 34) inside the contact hole 20 may be further removed, in order to form the recess (concave portion 26) much deeper. For example, the upper portion of the first conductive layer 33 may be etched (for example, by dry etching). By so doing, the barrier layer 60 to be described below can be formed much thicker.

In this manner, the plug 34 can be formed from the first conductive layer 33. An upper surface of the plug 34 is at a position lower than the upper surface of the dielectric layer 12. In other words, the concave portion 26 is formed above the plug 34. Also, the plug 34 is formed inside the barrier layer 32.

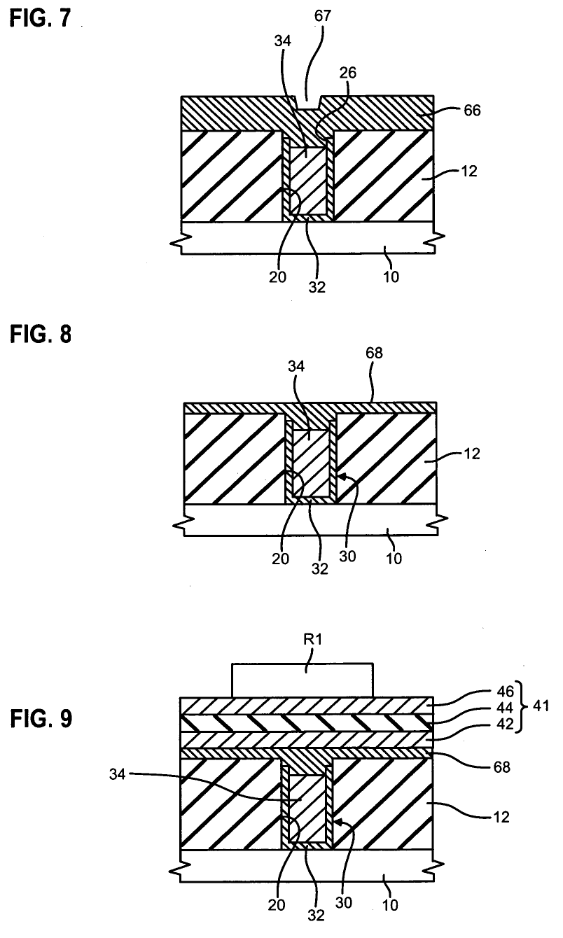

Next, as shown in FIG. 7, a second conductive layer 66 is formed on the plug 34 inside the contact hole 20 (in other words, in the concave portion 26) and on the dielectric layer 12. The second conductive layer 66 is formed in a manner to embed the concave portion 26. The second conductive layer 66 may be formed by sputtering or the like. As shown in FIG. 7, a concave portion 67 may be formed in the second conductive layer 66 above the contact hole 20.

Then, as shown in FIG. 8, the second conductive layer 66 is polished, thereby forming a barrier layer 68. The second conductive layer 66 may be polished by a chemical mechanical polishing method. The details of the process for polishing the second conductive layer 66 correspond to the details of the process for polishing the first conductive layer 33 described above. However, in this process, the second conductive layer 66 is polished to a predetermined thickness to be remained on the dielectric layer 12. In other words, in this process, the polishing step is finished before the dielectric layer 12 is exposed, so that the dielectric layer 12 that is a base of the second conductive layer 66 is not exposed. This is can be sufficiently accomplished by polishing only the second conductive layer 66 (for example, the second conductive layer 66 and the dielectric layer 12 do not have to be polished at the same time), and therefore a recess that may be caused by a difference in the polishing rate among different kinds of materials can be prevented from being generated. It is noted that the second conductive layer 66 may preferably be polished to the extent that at least the concave portion 67 is eliminated. By so doing, the upper surface of the second conductive layer 66 (the barrier layer 60) can be planarized.

In this manner, the contact section 30 can be formed. According to the present embodiment, the recess (concave portion 26) created in the process of forming the plug 34 is eliminated by the formation of the barrier layer 68, such that the upper surface of the contact section 30 and the upper surface of the dielectric layer 12 are generally flush with each other. Accordingly, a ferroelectric capacitor 40 to be described below can be formed on a flat surface. It is noted that the materials and properties of the barrier layer 32, the plug 34 and the barrier layer 68 (the barrier layer 60) are the same as those described in conjunction with the structure.

As shown in FIG. 9, a ferroelectric capacitor 40 is formed in a region including above the plug 34. Concretely, a lower electrode 42, a ferroelectric layer 44 and an upper electrode 46 are successively laminated to form a laminated body 41, and the laminated body 41 is patterned in a specified configuration.

As a method for forming the lower electrode 42, a sputtering method, a vacuum vapor deposition method, a CVD method, or the like may be used. As a method for forming the ferroelectric layer 44, a solution coating method (including a sol-gel method, a MOD (Metal Organic Decomposition) method, or the like), a MOCVD (Metal Organic Chemical Vapor Deposition) method, or the like can be used. It is noted that the upper electrode 46 can be formed by using a like method applied to the lower electrode 42.

Then, the laminated body 41 is patterned. By using a photolithography technique, a resist layer R1 may be formed on the laminated body 41, and portions of the laminated body 41 exposed through the resist layer R1 may be removed by etching, as shown in FIG. 9. In this case, the barrier layer 68 may be patterned in the same process of patterning the laminated body 41. In other words, both of the laminated body 41 and the barrier layer 68 may be patterned at the same time by the etching process to remove portions exposed through the resist layer R1. A portion of the barrier layer 68 above the dielectric layer 12 is removed. In this manner, the barrier layer 60 having the aforementioned first and second sections 62 and 64 can be formed. According to the above, the ferroelectric capacitor 40 and the barrier layer 60 can be formed through patterning in the same process, such that the manufacturing process can be simplified.

When the ferroelectric capacitor 40 is formed by patterning the laminated body 41, an anneal treatment in an oxygen atmosphere is conducted for stabilization of the ferroelectric layer 44 (for example, for etching damage recovery). In the present embodiment, because the barrier layer 68 is formed on the plug 34, oxidation of the plug 34 can be prevented. As a result, an increase in the resistance and a volume expansion of the plug 34 can be prevented.

According to the method for manufacturing a ferroelectric memory in accordance with the present invention, the barrier layer 60 is formed in a wide area that extends from the contact hole 20 over the dielectric layer 12, such that oxidation of the plug 34 can be prevented, and the adhesion to the lower electrode 42 of the ferroelectric capacitor 40 can be improved. Also, because the barrier layer 60 can be formed by polishing the second conductive layer 66 that has been formed, for example, the film forming step does not need to be conducted multiple times, and therefore the manufacturing process can be simplified. Furthermore, in the step of polishing the barrier layer 60, only the second conductive layer 66 is polished, and therefore a recess that may be caused by a difference in the polishing rate among different kinds of materials can be prevented from being generated.

### Second Embodiment

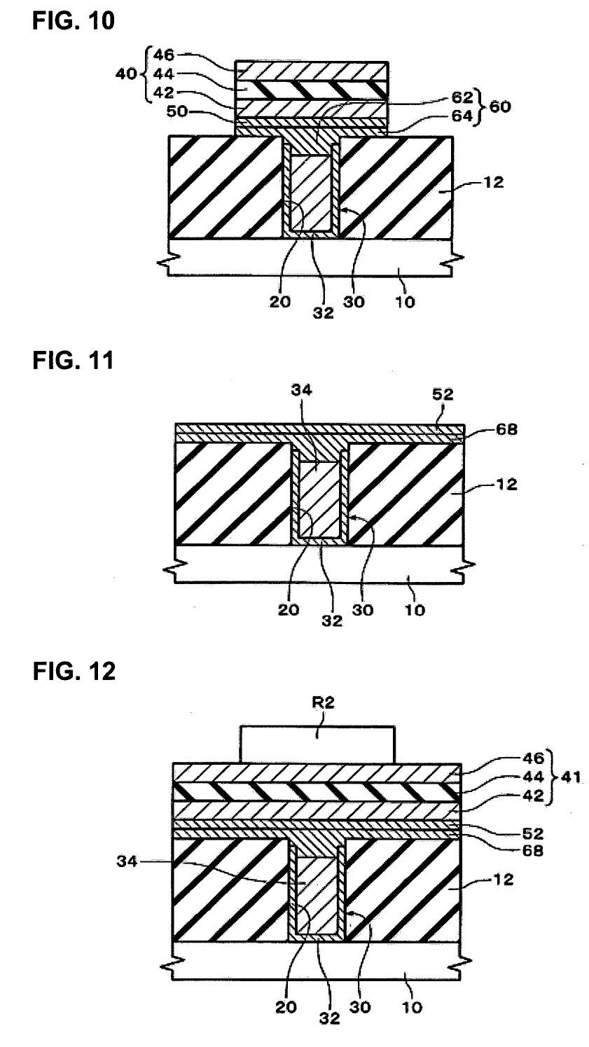

FIG. 10 is a view schematically showing a ferroelectric memory in accordance with a second embodiment of the present invention.

The ferroelectric memory in accordance with the present embodiment includes the composition of the ferroelectric memory described above, and further includes an adhesion layer 50.

The adhesion layer 50 is formed between a lower electrode 42 and a barrier layer 60 (a contact section 30). As shown in FIG. 10, the lower electrode 42 may be formed on one of surfaces of the adhesion layer 50, and the barrier layer 36 may be formed on the other surface. Also, the adhesion layer 50 is formed in a region including the lower electrode 42. In other words, in a plan view viewed in a direction orthogonal to the surface of the base member 10, a plane area of the adhesion layer 50 includes at least a plane area of the lower electrode 42. For example, the plane area of the adhesion layer 50 may generally match with the plane area of the lower electrode 42 (and the barrier layer 60). The adhesion layer 50 can improve adhesion of the contact section 30 and the dielectric layer 12 to the ferroelectric capacitor 40.

The adhesion layer 50 may be formed from the same material as that of the barrier layer 60 (for example, a TiAlN layer or a TiN layer), or may be formed from a different material. The adhesion layer 50 has a greater adhesion to the lower electrode 42 than to the plug 34. When the adhesion layer 50 is formed from a material different from that of the barrier layer 60, the adhesion layer 50 may have even a greater adhesion to the lower electrode 42 than to the barrier layer 60.

Next, a method for manufacturing a ferroelectric memory in accordance with the present embodiment is described. FIG. 11 and FIG. 12 are views schematically showing the method for manufacturing a ferroelectric memory in accordance with the present embodiment.

As shown in FIG. 11, after the contact section 30 is formed in the contact hole 20, an adhesion layer 52 is formed on the barrier layer 68. For example, the adhesion layer 52 may be formed by sputtering or the like.

Then, as shown in FIG. 12, a laminated body 41 that becomes a ferroelectric capacitor 40 is formed on the adhesion layer 52, and the laminated body 41, the barrier layer 68 and the adhesion layer 52 are patterned in the same process. When the patterning is conducted by using a photolithography technique, a resist layer R2 is formed on the laminated body 41, and portions of the laminated body 41 exposed through the resist layer R2 are removed by etching. By the same etching process, the laminated body 41, the barrier layer 68 and the adhesion layer 52 may be patterned at the same time. Accordingly, the ferroelectric capacitor 40, the barrier layer 60 and the adhesion layer 50 can be patterned and formed by the same process, such that the manufacturing process can be simplified.

It is noted that other compositions and effects of the present embodiment include the compositions and effects that can be derived from the description of the first embodiment.

The present invention is not limited to the embodiments described above, and many modifications can be made. For example, the present invention may include compositions that are substantially the same as the compositions described in the embodiments (for example, a composition with the same function, method and result, or a composition with the same objects and results). Also, the present invention includes compositions in which portions not essential in the compositions described in the embodiments are replaced with others. Also, the present invention includes compositions that achieve the same functions and effects or achieve the same objects of those of the compositions described in the embodiments. Furthermore, the present invention includes compositions that include publicly known technology added to the compositions described in the embodiments.

What is claimed is:

1. A ferroelectric memory comprising:
a base member;
a dielectric layer formed above the base member;
a contact hole that penetrates the dielectric layer;
a plug formed inside the contact hole;
a barrier layer formed above the plug, and including a first portion with a portion formed in the contact hole and a second portion formed integrally with the first portion and above the dielectric layer; and
a ferroelectric capacitor formed from a lower electrode, a ferroelectric layer and an upper electrode successively laminated in a region including above the plug.

2. A ferroelectric memory according to claim 1, wherein an upper surface of the barrier layer is flat.

3. A ferroelectric memory according to claim 1, wherein the barrier layer is formed in a region including the lower electrode.

4. A ferroelectric memory according to claim 1, wherein the barrier layer includes one of a titanium aluminum nitride layer and a titanium nitride layer.

5. A ferroelectric memory according to claim 1, further comprising an adhesion layer that is formed between the lower electrode and the barrier layer, and is formed in a region including the lower electrode.

6. A ferroelectric memory according to claim 1, further comprising another barrier layer formed along an inner surface of the contact hole, wherein the plug is formed inside the another barrier layer.

7. A method for manufacturing a ferroelectric memory, comprising:
(a) forming a contact hole that penetrates a dielectric layer formed above a base member;
(b) forming a first conductive layer inside the contact hole and above the dielectric layer;
(c) forming a plug inside the contact hole, having an upper surface at a position lower than an upper surface of the dielectric layer, by polishing the first conductive layer until the dielectric layer is exposed;
(d) forming a second conductive layer inside the contact hole and above the dielectric layer;
(e) forming a barrier layer formed above the plug, and including a first portion with a portion formed inside the contact hole and a second portion formed integrally with the first portion and above the dielectric layer by polishing the second conductive layer to a predetermined thickness remaining above the dielectric layer; and
(f) forming a ferroelectric capacitor by successively laminating a lower electrode, a ferroelectric layer and an upper electrode in a region including above the plug.

8. A method for manufacturing a ferroelectric memory according to claim 7, further comprising forming another barrier layer along an inner surface of the contact hole before the step (b), wherein the plug is formed inside the another barrier layer in the step (c).

9. A method for manufacturing a ferroelectric memory according to claim 7, wherein at least one of the step (c) and the step (e) includes a step conducted by a chemical mechanical polishing method.

10. A method for manufacturing a ferroelectric memory according to claim 7, wherein, in the step (c), an upper portion of the first conductive layer inside the contact hole is further removed by etching.

11. A method for manufacturing a ferroelectric memory according to claim 7, wherein, in the step (f), the lower electrode, the ferroelectric layer and the upper electrode are successively laminated to form a laminated body, and the laminated body and the barrier layer are patterned in a common process.

12. A method for manufacturing a ferroelectric memory according to claim 7, further comprising forming an adhesion layer in a region including above the barrier layer, after the step (e), wherein the ferroelectric capacitor is formed above the adhesion layer in the step (f).

13. A method for manufacturing a ferroelectric memory according to claim 12, wherein, in the step (f), the lower electrode, the ferroelectric layer and the upper electrode are successively laminated to form a laminated body, and the laminated body, the barrier layer and the adhesion layer are patterned in a common process.
